(19) United States
(12) Patent Application Publication
(10) Pub. No.: US 2025/0167019 A1
(43) Pub. Date: May 22, 2025

(54) CERAMIC HEATER

(71) Applicant: MiCo Ceramics Ltd., Anseong-si (KR)

(72) Inventors: Jung-Chul Jin, Anseong-si (KR); Hyung-Jun Cho, Anseong-si (KR); Myeong-Joon Kim, Anseong-si (KR)

(21) Appl. No.: 18/947,923

(22) Filed: Nov. 14, 2024

(30) Foreign Application Priority Data
Nov. 16, 2023 (KR) 10-2023-0159002

(51) Int. Cl. H01L 21/67; H05B 3/28

(52) U.S. Cl. CPC H01L 21/67248; H01L 21/67103; H05B 3/283

(57) ABSTRACT

An embodiment of the present disclosure provides a ceramic heater including a plate having a heat-generation body and a first passage, a shaft having a hollow, and a thermocouple inserted into the first passage, wherein the first passage includes an A-th passage part parallel with a first surface of the plate and a B-th passage part inclined with respect to the first surface. Furthermore, an embodiment of the present disclosure provides a ceramic heater including a plate having a heat-generation body and a first passage, a shaft having a hollow, and a thermocouple inserted into the first passage, wherein the first passage includes an A-th passage part parallel with an upper surface of the plate, and a C-th passage part disposed between the A-th passage part and an upper end portion of the shaft and gradually narrowing from the upper end portion of the shaft to the A-th passage.

### CROSS-REFERENCE TO RELATED APPLICATION(S)

This application is based on and claims priority under 35 U.S.C. 119 to Korean Patent Application No. 10-2023-0159002, filed on Nov. 16, 2023, in the Korean Intellectual Property Office, the disclosure of which is herein incorporated by reference in its entirety.

### BACKGROUND OF THE INVENTION

### 1. Field of the invention

The present disclosure relates to a ceramic heater and, more specifically, to a ceramic heater having an improved insertion structure for a temperature sensor.

### 2. Description of the Prior Art

Typically, in order to manufacture a flat panel display or semiconductor device, a process is performed where a series of layers, including dielectric layers and metal layers, are sequentially stacked and patterned on substrates such as glass substrates, flexible substrates, or semiconductor substrates. In this case, the series of layers, including dielectric layers and metal layers, may be deposited on the substrate by a process such as chemical vapor deposition (CVD) or physical vapor deposition (PVD).

In order to uniformly configure these layers, the substrate needs to be heated at a consistent temperature, for which a substrate heating device may be used to heat and support the substrate. The substrate heating device may be used for heating a substrate during an etching process of the dielectric layer or metal layer disposed on the substrate, and a firing process of a photo resistor.

A ceramic heater used as the substrate heating device includes a heat-generation body and a thermocouple to measure a temperature of the heat-generation body. The thermocouple may be inserted into a thermocouple passage disposed inside the ceramic heater and heat generated from the heat-generation body may be emitted through the thermocouple passage. Such heat loss causes a problem in which the temperature uniformity of the substrate disposed on the ceramic heater deteriorates.

### SUMMARY OF THE INVENTION

An aspect to be addressed is to prevent heat loss due to a passage into which a temperature sensor, such as a thermocouple is inserted.

Furthermore, an aspect to be addressed is to prevent cracks occurring in a plate of a ceramic heater due to expansion and contraction of a heat-generation body.

Furthermore, an aspect to be addressed is to measure a temperature of a heat-generation body more accurately.

Furthermore, an aspect to be addressed is to minimize a space volume of a thermocouple passage for installation of a temperature sensor including a thermocouple and increase the success rate of insertion by facilitating thermocouple insertion.

A ceramic heater according to an embodiment of the present disclosure includes a plate having a heat-generation body and a first passage, a shaft having a hollow, and a thermocouple inserted into the first passage, wherein the first passage includes an A-th passage part parallel with a first surface of the plate and a B-th passage part inclined with respect to the first surface.

The plate includes a first plate part and a second plate part, the A-th passage part is located in the first plate part, and the B-th passage part is located in the second plate part.

The B-th passage part is inclined in a direction to the heat-generation body.

The B-th passage part is located at an end portion of the first passage in a direction to circumference.

An exit area of the A-th passage part is smaller than an entrance area of the B-th passage part.

A temperature measurement part of the thermocouple is located in the B-th passage part.

A ceramic heater according to another embodiment of the present disclosure includes a plate having a heat-generation body and a first passage, a shaft having a hollow, and a thermocouple inserted into the first passage, wherein the first passage includes an A-th passage part parallel with an upper surface of the plate, and a C-th passage part disposed between the A-th passage part and an upper end portion of the shaft and gradually narrowing from an upper end portion of the shaft to the A-th passage.

A thermocouple guide disposed inside the hollow of the shaft and having an upper end portion meeting the C-th passage part is further included and the thermocouple is located in the C-th passage part, in the A-th passage part, and inside the thermocouple guide.

An end portion of the thermocouple guide may be inserted into and fixed to a groove of the plate connected to the C-th passage part.

A flat part of an end portion of the thermocouple guide may be inserted into and fixed to a groove of the plate connected to the C-th passage part.

A filling-type protrusion part of an end portion of the thermocouple guide may be inserted into and fixed to a groove of the plate and the C-th passage part.

A protrusion part of an end portion of the thermocouple guide may be inserted into and fixed to a groove of the plate connected to the C-th passage part.

A groove part of an end portion of the thermocouple guide may be inserted into and fixed to a groove of the plate connected to the C-th passage part.

A screw part of an end portion of the thermocouple guide may be fastened and fixed to a screw part of the groove of the plate connected to the C-th passage part.

According to an embodiment of the present disclosure, the disposition of a passage, into which a temperature sensor is inserted, on an area in which heat-generation bodies are not concentrated may prevent heat loss and cracks on a ceramic plate.

Furthermore, the disposition of a temperature measurement body of the temperature sensor close to a heat generation body may allow more accurate measurement of the temperature of the heat generation body.

Furthermore, the installation of a thermocouple guide fixed within a shaft and the use of a passage of a plate having a curvature allowing a space volume of a thermocouple passage to be minimized may enable easy insertion of a temperature sensor such as a thermocouple, significantly increasing the success rate of insertion.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a perspective view illustrating a ceramic heater according to an embodiment of the present disclosure;

FIG. 2 is a sectional view of a plate when the plate is cut horizontally along a heat-generation body and viewed from above according to an embodiment of the present disclosure;

FIG. 3 is a sectional view of a plate when the plate is cut horizontally along a heat-generation body and viewed from above according to another embodiment of the present disclosure;

FIG. 4 is a partial enlarged view of a P portion in FIG. 2;

FIG. 5 is a sectional view of a plate when the plate is cut horizontally along a heat-generation body and viewed from above according to still another embodiment of the present disclosure;

FIG. 6 is a sectional view taken along C-C of FIG. 2;

FIG. 7 is a view of a comparative example showing heat loss caused when a first passage is disposed on area on which heat-generation bodies are concentrated;

FIG. 8 is a view of a comparative example showing a microcrack caused when a first passage is disposed on area on which heat-generation bodies are concentrated;

FIG. 9 is a sectional view of a plate taken along C-C according to still another embodiment of the present disclosure;

FIG. 10 is a view illustrating a process of manufacturing the plate in FIG. 9;

FIG. 11 is a partial enlarged view of a Z portion in FIG. 9;

FIG. 12 is a sectional view taken along E-E of FIG. 11;

FIG. 13 illustrates a portion of a sectional view taken along B-B of FIG. 1;

FIG. 14 is an enlarged view of another embodiment with respect to a coupling portion of a plate and a shaft in the sectional view taken along B-B in FIG. 1;

FIG. 15 is an enlarged view of still another embodiment with respect to a coupling portion of a plate and a shaft in the sectional view taken along B-B in FIG. 1;

FIG. 16 is an enlarged view of still another embodiment with respect to a coupling portion of a plate and a shaft in the sectional view taken along B-B in FIG. 1;

FIG. 17 is an enlarged view of still another embodiment with respect to a coupling portion of a plate and a shaft in the sectional view taken along B-B in FIG. 1;

FIG. 18 is an enlarged view of still another embodiment with respect to a coupling portion of a plate and a shaft in the sectional view taken along B-B in FIG. 1;

FIG. 19 is an enlarged view of still another embodiment with respect to a coupling portion of a plate and a shaft in the sectional view taken along B-B in FIG. 1; and

FIG. 20 is an enlarged view of an example of a coupling portion of a plate and a shaft in case that a thermocouple guide is not fixed.

### DETAILED DESCRIPTION OF THE EXEMPLARY EMBODIMENTS

In reference to the attached drawings, detailed descriptions of the embodiments disclosed in the disclosure will be provided and identical or similar components, regardless of the drawing numerals, are assigned the same reference numbers, and redundant explanations regarding these components will be omitted. In the following description of the embodiments according to the present disclosure, when each layer (film), area, pad, or pattern is described as being disposed “on” or “under” a substrate, layer (film), area, pad, or pattern, the terms “on” and “under” include both “direct” and “indirect via an intervening layer” disposition configurations. In addition, the standards for top/top or bottom/bottom of each layer are explained based on the drawing. In the drawings, the thickness or size of each layer is exaggerated, omitted, or schematically shown for convenience and clarity of explanation. Furthermore, the size of each component does not fully reflect the actual size.

In this description, expressions such as “comprising”, “provided”, or “including” are intended to indicate certain features, numbers, steps, operations, elements, parts or combinations thereof, and one or more than those described and it should not be construed to exclude the existence or possibility of any other characteristic, number, step, operation, element, or part or combination thereof.

In addition, terms such as “first” and “second” may be used to describe various components, but the components are not limited by the terms, and the terms are used only for the purpose of distinguishing one component from another.

In the following description of the disclosure, a detailed description of related prior art incorporated herein will be omitted when it is determined that the description may make the subject matter of embodiments disclosed in the disclosure unclear.

The accompanying drawings are only for easy understanding of the embodiments disclosed in the present specification, and the technical ideas disclosed in the present specification are not limited by the accompanying drawings and it should be understood to include all modifications, equivalents and substitutes included in the spirit and scope of the present disclosure.

Hereinafter, various embodiments of the present disclosure will be described in detail with reference to the drawings.

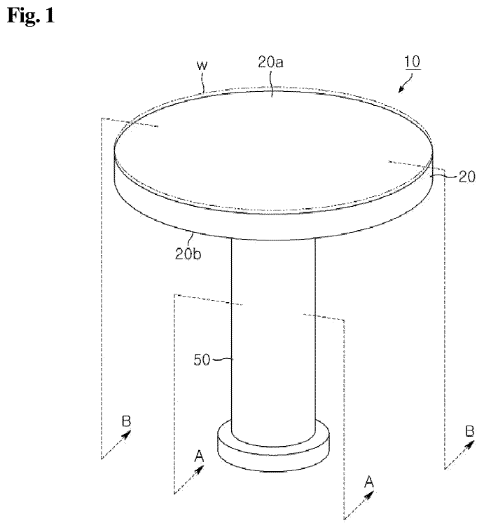

FIG. 1 is a perspective view illustrating a ceramic heater according to an embodiment of the present disclosure.

The ceramic heater 10 corresponds to a device configured to support heat treatment objects for various purposes, such as semiconductor wafers, glass substrates, and flexible substrates and heat the corresponding heat treatment objects to a predetermined temperature.

The ceramic heater 10 includes a plate 20 on which a heat treatment object like a semiconductor wafer W is mounted and a shaft 50 coupled to a lower surface 20b of the plate. The plate 20 includes a mounting surface (first surface) 20a corresponding to a flat upper surface on which a heat treatment object is mounted and a lower surface (second surface) 20b to which the shaft 50 is coupled.

The plate 20 corresponds to a disc-shaped plate 20 including a ceramic material such as aluminum nitride or alumina. The shaft 50 may be configured by ceramic, such as aluminum nitride or alumina as the plate 20.

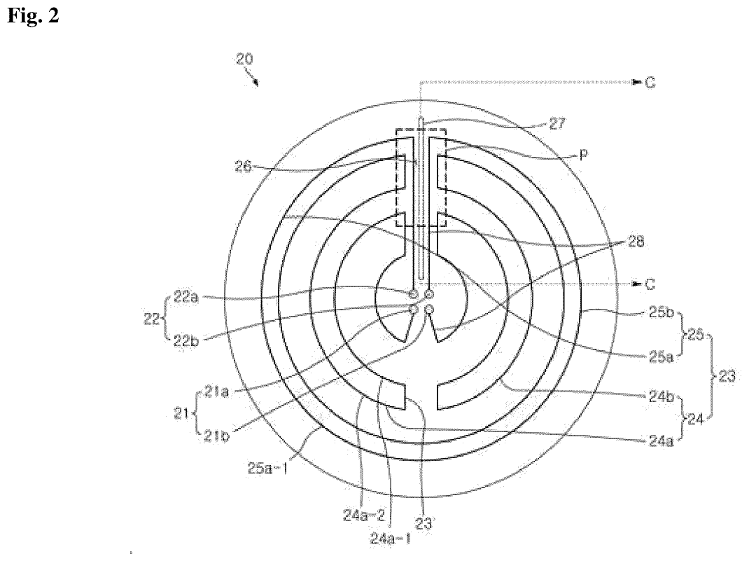

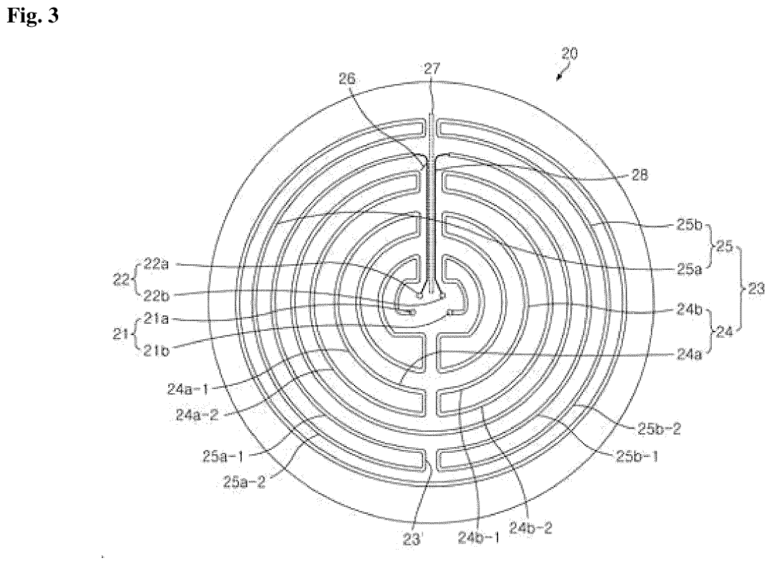

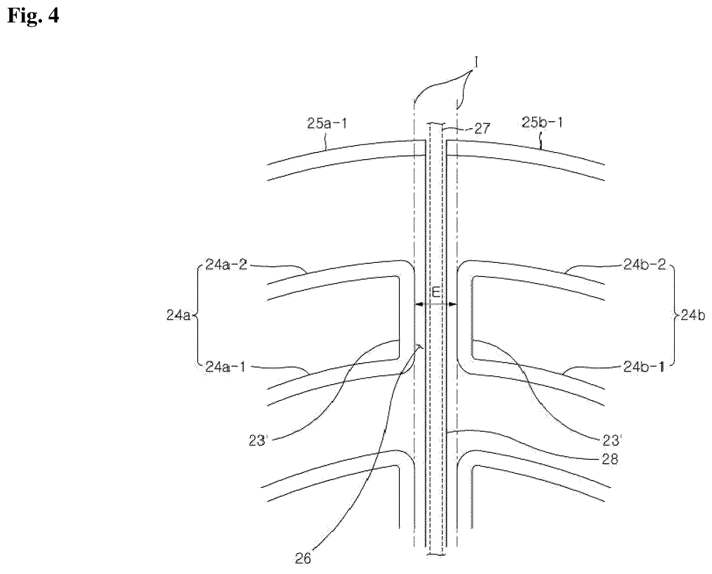

FIG. 2 is a sectional view of a plate when the plate is cut horizontally along a heat-generation body and viewed from above according to an embodiment of the present disclosure, FIG. 3 is a sectional view of a plate when the plate is cut horizontally along a heat-generation body and viewed from above according to another embodiment of the present disclosure, and FIG. 4 is a partial enlarged view of a P portion in FIG. 2.

Referring to FIGS. 2 to 4, the plate 20 may be configured by a ceramic material and A₂O₃, Y₂O₃, Al₂O₃/Y₂O₃, ZrO₂, AlC, TiN, AlN, TiC, MgO, Cao, CeO₂, TiO₂, BₓC_{y}, BN, SiO₂, SiC, YAG, Mullite, AlF₃ or two or more of these may be used in combination.

The plate 20 may include a heat-generation body 23. The heat-generation 23 may function to heat a heat treatment object located on the mounting surface 20a of the plate at a constant temperature for smooth deposition and etching processes in a semiconductor manufacturing process or the like.

The heat-generation body 23 may be embedded in the plate 20 at a position corresponding to that of the heat treatment object. In order to uniformly heat the entire heat treatment object by means of heat generation, the heat-generation body 23 may be embedded in the plate 20 parallel to the mounting surface 20a of the plate so as to enable uniform temperature control depending on a position and ensure that a distance for heat transfer to the heat treatment object remains consistent across nearly all positions.

The heat-generation body 23 may be configured to have a shape corresponding to that of the heat treatment object. In addition, the heat-generation body 23 may be configured to have a plate-like coil shape by heating wire (or resistance wire) or a flat plate shape. The heat-generation body 23 may be configured by tungsten (W), molybdenum (Mo), molybdenum carbide (Mo₂C, MoC, or Mo₃C₂), silver (Ag), gold (Au), platinum (Pt), niobium (Nb), titanium (Ti), or alloys thereof. The heat-generation body 23 may be electrically connected to a terminal 21 or 22 through a conductive connection part 28.

A pair of first terminals 21 and a pair of second terminals 22 may be disposed on a center part of the plate 20. The first terminal 21 electrically connects an inner zone heat-generation body 24 disposed in an inner area of the plate 20 and a power supply load inside the shaft 50 and the second terminal 22 electrically connect an outer zone heat-generation body 25 disposed on an outer area of the plate 20 and a power supply load inside the shaft 50.

The heat-generation body 23 of the present disclosure may include two or more heat-generation bodies to heat multiple compartmentalized zones. By way of example, FIG. 2 illustrates the heat-generation body 23 including the inner zone heat-generation 24 and the outer zone heat-generation body 25 to heat each zone by dividing the plate into an inner zone and an outer zone. Hereinafter, although the heater compartmentalized into the inner zone and the outer zone is described, the present disclosure is not limited thereto. For example, it is also understood that the present disclosure may be applied to a multi-zone heater with a ceramic heater plate, where the plate is compartmentalized into fan-shaped segments at predetermined angles, each segment having a corresponding heat-generation body.

The inner zone heat-generation body 24 starts from a first terminal 21a, configures a predetermined pattern like a concentric circle, is continuously wired in the inner area of the plate 20, and then is connected to a first terminal 21b. In this process, the inner zone heat-generation body 24 may be folded at multiple connection parts 23′ to configure a multiple concentric circle pattern shape.

Multiple concentric circle patterns of the inner zone heat-generation body 24 may include multiple concentric arc parts 24a-1, 24a-2, 24b-1, and 24b-2 extending along a circumferential direction of the plate 20. In addition, the multiple connection parts 23′ which connect adjacent arc parts 24a-1, 24a-2, 24b-1, and 24b-2 among the multiple concentric arc parts 24a-1, 24a-2, 24b-1, and 24b-2. Adjacent arc parts 24a-1, 24a-2, 24b-1, and 24b-2 may be connected through the connection parts 23′ extending in the diametric direction.

The multiple concentric arc parts 24a-1, 24a-2, 24b-1, and 24b-2 may have different diameters from each other. In addition, the multiple connection parts 23′ may be aligned in parallel with each other to define a spaced area 26 extending in the radial direction of the plate 20 therebetween on the plate 20.

The inner zone heat-generation body 24 may include a first inner heat-generation part 24a and a second inner heat-generation body 24b. The first inner heat-generation part 24a and the second inner heat-generation body 24b may be configured to be connected to each other while configuring an axisymmetric structure based on the diametric direction of the plate 20.

An arc part 24a-1 of the first inner heat-generation part 24a and an arc part 24b-1 of the second inner heat-generation body 24b have an identical diameter. The arc part 24a-2 of the first inner heat-generation part 24a and the arc part 24b-2 of the second inner heat-generation body 24b have an identical diameter greater than those of the arc part 24a-1 and the arc part 24b-1. The arc part 24a-1 is connected to the arc part 24a-2 by a connection part 23′.

The arc part 24b-1 is connected to the arc part 24b-2 by a connection part 23′.

The connection part 23′ of the first inner heat-generation part 24a and the connection part 23′ of the second inner heat-generation part 24b may be disposed spaced a predetermined distance E apart from each other to face each other. The spaced space 26 in which the inner zone heat-generation body 24 is not wired within an area configured by a virtual line I generated by the connection parts 23′ being spaced apart may be disposed on the plate 20. The spaced area 26 may extend in the radial direction of the plate 20.

The spaced area 26 may be disposed between the first inner heat-generation part 24a and the second inner heat-generation part 24b and may be preferably disposed within an area configured by multiple connection parts 23′ aligned parallel to each other and extending in the radial direction of the plate 20. The spaced area 26 may be configured from the center part of the plate 20 in the radial direction.

The outer zone heat-generation body 25 starts from a second terminal 22a, configures a predetermined pattern like a concentric circle, is continuously wired in the outer area of the plate 20, and then is connected to a second terminal 22b. In this process, the outer zone heat-generation body 25 may be folded at predetermined positions to surround the inner zone heat-generation body 24 so as to configure a concentric circle pattern (see FIG. 2) or folded at the multiple connection parts 23′ to configure multiple concentric circle patterns (see FIG. 3).

Multiple concentric circle patterns of the outer zone heat-generation body 25 may include multiple concentric arc parts 25a-1, 25a-2, 25b-1, and 25b-2 extending along a circumferential direction of the plate 20. In addition, the multiple connection parts 23′ which connect adjacent arc parts 25a-1, 25a-2, 25b-1, and 25b-2 among the multiple concentric arc parts 25a-1, 25a-2, 25b-1, and 25b-2. Adjacent arc parts 25a-1, 25a-2, 25b-1, and 25b-2 may be connected through the connection parts 23′ extending in the diametric direction.

The multiple concentric arc parts 25a-1, 25a-2, 25b-1, and 25b-2 may have different diameters from each other. In addition, the multiple connection parts 23′ may be aligned in parallel with each other to define a spaced area 26 extending in the radial direction of the plate 20 therebetween on the plate 20.

The outer zone heat-generation body 25 may include a first outer heat-generation part 25a and a second outer heat-generation body 25b. The first outer heat-generation part 25a and the second outer heat-generation body 25b may be configured to be connected to each other while configuring an axisymmetric structure based on the diametric direction of the plate 20.

An arc part 25a-1 of the first outer heat-generation part 25a and an arc part 25b-1 of the second outer heat-generation body 25b have an identical diameter. The outer zone heat-generation body 25 may additionally include an arc part 25a-2 of the first outer heat-generation part 25a and an arc part 25b-2 of the second outer heat-generation body 25b. The arc part 25a-2 and the arc part 25b-2 have an identical diameter greater than those of the arc part 25a-1 and the arc part 25b-1. The arc part 25a-1 is connected to the arc part 25a-2 by a connection part 23′. The arc part 25b-1 is connected to an arc part 25b-2 by the connection part 23′.

The connection part 23′ of the first outer heat-generation part 25a and the connection part 23′ of the second outer heat-generation part 25b may be disposed spaced a predetermined distance E apart from each other to face each other. The spaced space 26 in which the outer zone heat-generation body 25 is not wired within an area configured by a virtual line I generated by the connection parts 23′ being spaced apart may be disposed on the plate 20. The spaced area 26 may extend in the radial direction of the plate 20.

The spaced area 26 may be disposed between the first outer heat-generation part 25a and the second outer heat-generation part 25b and may be preferably disposed within an area configured by multiple connection parts 23′ aligned parallel to each other and extending in the radial direction of the plate 20. In addition, the spaced area 26 may be configured between a conductive connection part 28 connected to the second terminal 22a and a conductive connection part 28 connected to the second terminal 22b. The spaced area 26 may extend from the spaced area 26 disposed in the inner area from the center part of the plate 20 in the radial direction.

The inner zone heat-generation body 24 and the outer zone heat-generation body 25 may be electrically separated and independently drive.

The plate 20 may include a first passage 27 to which a temperature sensor 60 like a thermocouple is inserted. The first passage 27 may be configured along the spaced area 26 to be adjacent to the spaced space 26. In addition, the first passage 27 may be disposed parallel to the mounting surface 20a of the plate.

As shown in FIGS. 2 to 4, when viewed from above the plate 20 in the thickness direction of the plate 20, the first passage 27 may be disposed adjacent to the spaced area 26 not to overlap the heat-generation body 23. In addition, the first passage 27 may be disposed adjacent to the spaced area 26 configured between the conductive connection part 28 connected to the second terminal 22a and the conductive connection part 28 connected to the second terminal 22b.

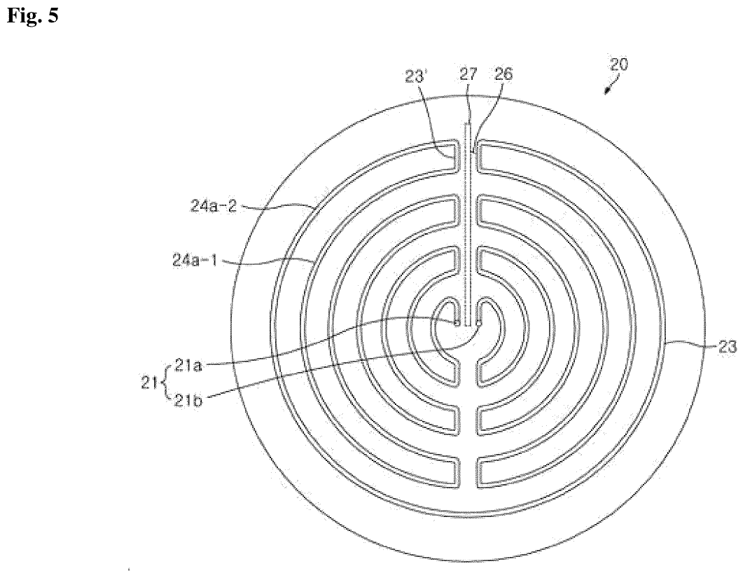

As shown in FIGS. 2 and 3, multiple heat-generation bodies, for example, two heat-generation bodies 24 and 25 may be disposed independently of each other on the plate 20, and as shown in FIG. 5, one single heat-generation body 23 may be disposed on the entire area of the plate 20.

In addition, the plate 20 may include multiple spaced areas 26 and multiple first passages 27. The spaced areas 26 and the first passages 27 may be disposed at multiple angular positions in the direction of circumference. In this case, the multiple first passages 27 may all have identical longitudinal length, but may be configured to have different longitudinal lengths depending on the design.

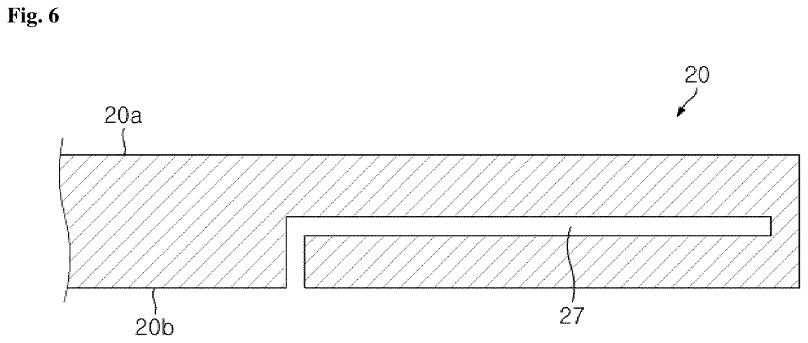

FIG. 6 is a sectional view taken along C-C of FIG. 2.

Referring to FIG. 6, since the first passage 27 is configured to be adjacent to the spaced area 26 along the spaced area 26, the heat-generation body 23 may not be disposed on an upper portion of the first passage 27 as shown in FIG. 6. By disposing the first passage 27 in an area in which heat-generation bodies 23 are not concentrated, heat generation from the heat-generation bodies 23 may be prevented from being lost through the first passage 27, thereby improving the temperature uniformity of the heater. In addition, cracks in vulnerable areas of the plate 20 due to expansion and contraction of the heat-generation body 23 may be prevented.

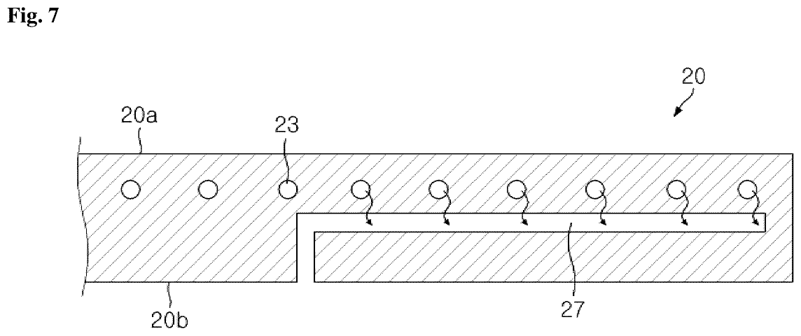

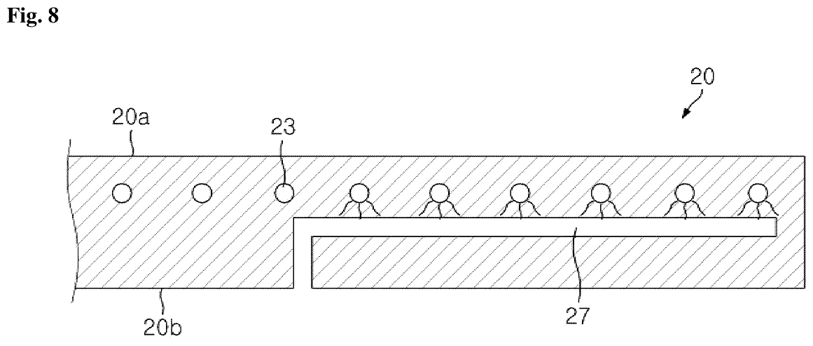

FIGS. 7 and 8 are views showing a case in which microcracks occur when a first passage is disposed in an area on which heat-generation bodies are concentrated.

As shown in FIG. 7, in case that the first passage 27 is disposed adjacent to the heat-generation body 23, heat generated from the heat-generation body 23 may be lost through the first passage 27.

Furthermore, as shown in FIG. 8, in case that the first passage 27 is disposed adjacent to the heat-generation body 23, expansion and contraction of the heat-generation body 23 may cause a microcrack on a thin portion of the plate 20.

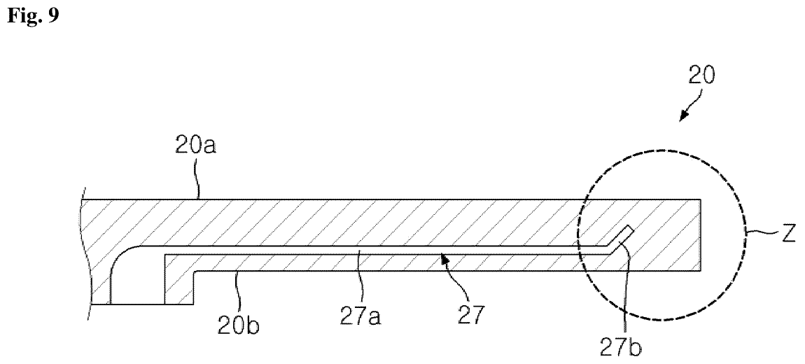

FIG. 9 is a sectional view of a plate taken along C-C according to still another embodiment of the present disclosure.

The temperature sensor 60 like a thermocouple is inserted into the first passage 27 of the plate 20. The first passage 27 may include an A-th passage part 27a disposed parallel to the mounting surface 20a of the plate and a B-th passage part 27b inclined with respect to the mounting surface 20a.

The B-th passage part 27b may be located at an end portion of the first passage 27 in the direction to circumference and have a temperature measurement part of the temperature sensor 60 located therein. The B-th passage part 27b may disposed inclined in a direction of the heat-generation body 23, thus minimizing a distance between the temperature measurement body of the temperature sensor 60 and the heat-generation body 23. Furthermore, by positioning the end portion of the B-th passage part 27b in the direction to circumference to have a height identical to that of the heat-generation body 23 in the thickness direction of the plate 20, that is, located in an identical plane, a temperature of an area between heat-generation body connection parts 23′ may be accurately measured.

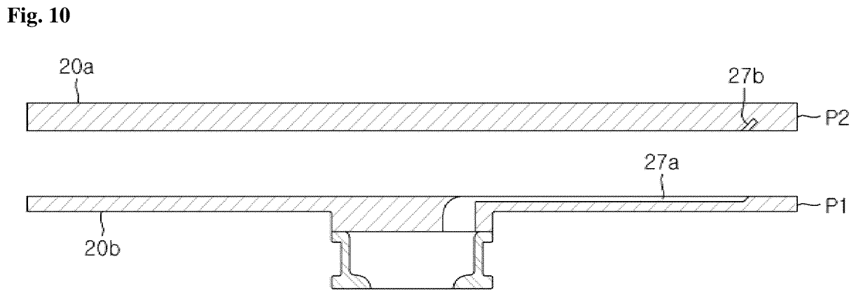

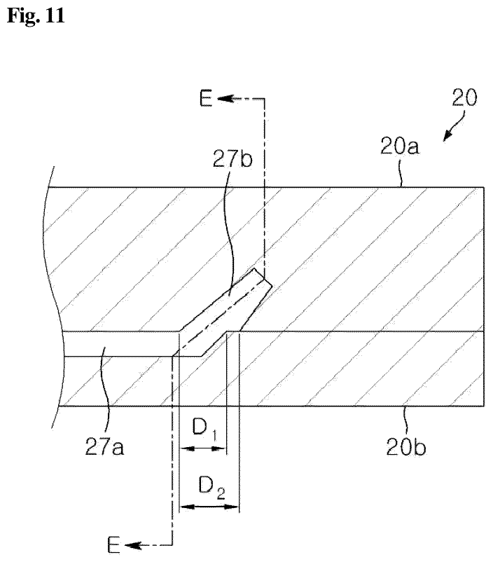

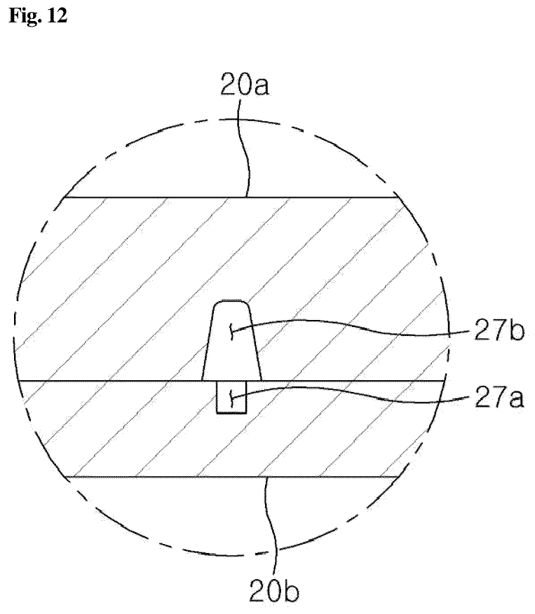

FIG. 10 is a view illustrating a process of manufacturing the plate 20 in FIG. 9, FIG. 11 is a partial enlarged view of a Z portion in FIG. 9, and FIG. 12 is a sectional view taken along the E-E direction of FIG. 11.

The plate 20 may include an upper plate P2 and a lower plate P1. The B-th passage part 27b may be disposed on the upper plate P2 and the A-th passage part 27a may be disposed on the lower plate P1.

The A-th passage part 27a and the B-th passage part 27b may have a shape of a groove or hole elongated in the circumferential direction of the plate 20 to allow the temperature sensor 60 like a thermocouple to be inserted thereto. The A-th passage part 27a and the B-th passage part 27b may have a cross-section of various shapes such as round, square, and the like.

The plate 20 may be manufactured by bonding the lower plate P1 and the lower plate P2 on which the A-th passage part 27a and the B-th passage part 27b are disposed. In this case, if the A-th passage part 27a and the B-th passage part 27b are not precisely aligned, the space for the temperature sensor 60 to pass through is reduced, making it difficult or even impossible to insert the temperature sensor 60 into the B-the passage part 27b.

For easy alignment when bonding the upper plate P2 and the lower plate P1, as shown in FIG. 11, the B-th passage part 27b may be processed to have a polyhedral shape, such as a cone, triangular pyramid, or square pyramid, a truncated cone shape, or truncated polyhedral pyramid shape. As such, a sectional area of an end portion of the B-th passage part 27b is configured to be small so that the temperature measurement part of the thermocouple inserted into the B-th passage part 27b is not shaken so as to improve temperature measurement accuracy.

When the upper plate P2 and the lower plate P1 are bonded, an exit of the A-th passage part 27a may be configured, which corresponds to a hole to allow the temperature sensor 60 to pass through one end of the A-th passage part 27a disposed on the lower plate p1. In addition, an entrance of the B-th passage part 27b corresponding to a hole to allow the temperature sensor 60 to pass therethrough at a position in contact with the exit of the A-th passage part 27a.

As the exit of the A-th passage part 27a and the entrance of the B-th passage part 27b come into contact with each other, the A-th passage part 27a and the B-th passage part 27b may integrally configure the first passage 27. Here, in order to ensure that the space through which the temperature sensor 60 passes is not reduced even if the A-th passage part 27a and the B-th passage part 27b are not exactly aligned, an entrance area D2 of the B-th passage part 27b may be configured to be greater than an exit area DI of the A-th passage part 27a.

In addition, by positioning a clearance space of the entrance area D2 of the B-th passage part 27b, that is, a space corresponding to “D2−D1”, to extend in a direction away from the center of the plate 20, the temperature sensor 60 such as a thermocouple may be easily inserted into the B-th passage part 27b. In other words, the thermocouple inserted through the A-th passage part 27a may be easily inserted along an inner wall of the B-th passage part 27b without hitting the upper plate P2 at the entrance of the B-th passage part 27b.

In addition, the B-th passage part 27b may be configured to have a cross-sectional area decreasing in a direction away from the center of the plate 20.

As such, by configuring the entrance area D2 of the B-th passage part 27b to be greater than the exit area DI of the A-th passage part 27a, an alignment error in the radial direction (left-right direction in FIG. 10) of the plate 20 may be accommodated when the plate 20 is assembled. Furthermore, as shown in FIG. 12, by configuring a width of the B-th passage part 27b to be greater than that of the A-th passage part 27a, an alignment error in a rotation direction (the circumferential direction of the plate) may be accommodated to assemble the plate 20.

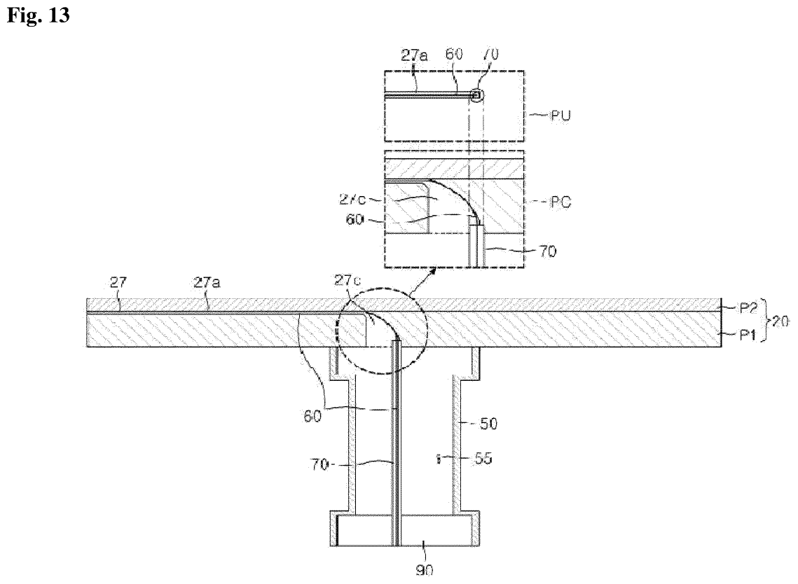

FIG. 13 illustrates a portion of a sectional view taken along B-B of FIG. 1. Here, reference will be made to a sectional view PC and a planar view PU for a coupling portion of the plate 20 and the shaft 50.

Referring to FIG. 13, the shaft 50 may be configured as a wall with a predetermined thickness and may be configured to have a cylindrical shape with a space (hollow) 55 therein. Multiple power supply loads (not shown) to be connected to terminals of the plate 20 may be installed in the inner space of the shaft 50. A predetermined mount 90 may be provided on a lower side of the shaft 50 and through this, multiple power supply loads (not shown) and a thermocouple 70 may be fixed to a lower side thereof.

Hereinafter, the description above may be applied to the components, such as the plate 20 including the heat-generation body 23 and the first passage 27, the shaft 50, and the thermocouple 60 as shown in FIGS. 1 to 13.

As described above, the plate 20 may include an upper plate P2 and a lower plate P1. As shown in FIG. 10, the B-th passage part 27b (omissible) may be disposed on the upper plate P2 and the A-th passage part 27a may be disposed on the lower plate P1.

Additionally, as shown in FIG. 13, the first passage 27 may include a C-th passage part 27c that gradually narrows from the upper end portion of the shaft 50 to the A-th passage part 27a between the A-th passage part 27a and the upper end portion of the shaft 50. The C-th passage part 27c may be disposed on the plate 20. In case that the lower plate P1 and the upper plate P2 are separated, the C-th passage part 27c may be disposed on the lower plate p1 and may be disposed to extend from the lower plate P1 to a portion of the upper plate P2.

Due to the C-th passage part 27c gradually narrowing from the end portion of the shaft 50 to the A-th passage part 27a, a space volume for a thermocouple path in the C-th passage part 27c may be minimized through a passage having a curvature of the plate 20 compared to the case in which the C-th passage 27c has a hexahedral shape. A distal temperature measurement part of the temperature sensor 60 comes in contact with the curved surface of the C-th passage part 27c to be pushed and inserted toward the A-th passage part 27a and to facilitate the insertion, the curved surface portion of the C-th passage part 27c is configured to have a rounded shape, such as a disk, a sphere, or an oval, extending from the upper end portion of the shaft 50 to the A-th passage part 27a. That is, the space of the C-th passage part 27c may have a shape for a portion of a shape having a curved surface such as a disk, a sphere, or an oval.

The temperature sensor 60 like a thermocouple may be inserted into the first passage 27 of the plate 20 via the thermocouple guide 70 having a through-hole provided inside a hollow 55 of the shaft 50. The thermocouple guide 70 is disposed inside the hollow 55 of the shaft 50 to allow the upper end portion thereof to meet the C-th passage part 27c. In other words, the temperature sensor 60 like a thermocouple may be disposed via the inside of the thermocouple guide 70, the C-th passage part 27c, and the A-th passage part 27a. As described above, the terminal temperature measurement part of the temperature sensor 60 may be pushed all the way to the end and inserted into the A-th passage part 27a. In case that the B-th passage part 27b is provided, the terminal temperature measurement part of the temperature sensor 60 may be pushed all the way to the end and inserted into the B-th passage part 27b.

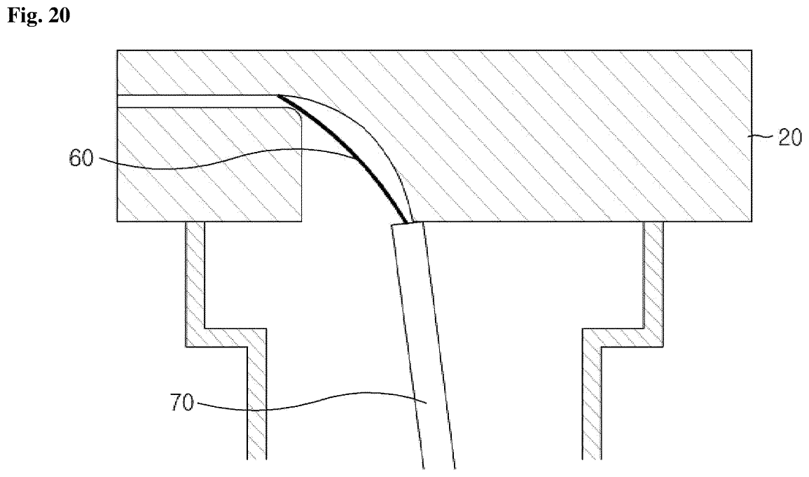

The end portion of the thermocouple guide 70 may be inserted into and fixed to a groove of the lower plate P1 or the plate 20 extending to the C-th passage part 27c. In case that the thermocouple guide 70 is not fixed as shown in FIG. 20, when the temperature sensor 60 is pushed and inserted through the thermocouple guide 70, the C-th passage part 27c, and the A-th passage part 27a, the insertion success rate decreases due to shaking or the like of the thermocouple guide 70.

There is a method (conventional method) in which the thermocouple guide is manufactured in a curved shape (not shown) so that an end thereof is close to the A-th passage part 27a, but in this case, the thermocouple guide is not fixed in addition to the problem that it is difficult to bring the end of the thermocouple guide close to the A-th passage part 27a, so the insertion success rate decreases due to the shaking or the like of the thermocouple during the process of inserting and pushing the thermocouple thereto.

Furthermore, in the conventional method, substantial processing space within the plate 20 is necessary for a process of inserting the curved thermocouple guide inside the shaft and allow the end portion of the thermocouple guide to be close to the A-th passage part 27a, the processing space may cause decrease in temperature uniformity of the plate, and heat loss through the thermocouple guide may cause a plate crack and hinder the maintenance of temperature uniformity.

Therefore, the present disclosure may facilitate thermocouple insertion by securing a straight thermocouple guide 70 within the shaft 50 and due to the C-th passage part 27c gradually narrowing from the end portion of the shaft 50 to the A-th passage part 27a, a space volume for a thermocouple path in the C-th passage part 27c may be minimized through a passage having a curvature of the plate 20 compared to the case in which the C-th passage 27c has a hexahedral shape. The C-th passage part 27c having a curvature may allow the distal temperature measurement part of the temperature sensor 60 to come in contact with the curved surface of the C-th passage part 27c to be pushed and inserted toward the A-th passage part 27a, significantly increasing the success rate of insertion.

The advantages of the structure using the curved surface of the C-th passage part 27c and the fixation of the straight thermocouple guide 70 within the shaft 50 are summarized in more detail as follows.

### 1) Thermocouple Passage Volume Reduction Effect

The improved structure of the present disclosure may, compared to structures of conventional technologies, not only improve the thermocouple insertion effect but also effectively reduce the volume of the thermocouple passage.
Furthermore, the reduction in the thermocouple passage volume may improve the temperature uniformity and durability of the plate 20.

### 2) Thermocouple Guide Removal Effect

The improved structure of the present disclosure may minimize the insertion of the thermocouple guide 70.
Furthermore, heat loss through the thermocouple guide 70 may be minimized so as to enhance the temperature uniformity of the plate 20 and prevent crack occurrence due to rapid heat loss.

### 3) Thermocouple Insertion Stability Improvement Effect

The improved structure of the present disclosure may cause the thermocouple to be bent by the curvature of the plate 20 when the thermocouple is inserted and, in this case, the fixed thermocouple guide 70 may serve as a supporter to allow the thermocouple to be bent according to the curvature of the plate 20.
Furthermore, improvement of the fixation force of the thermocouple guide 70 may increase the success rate of thermocouple insertion.
Furthermore, as the radius of curvature of the curved surface of the plate 20 becomes smaller, more force is applied to the plate 20 during insertion. The improvement of the fixation force of the thermocouple guide 70 may lead to the same effect even if the radius of curvature of the plate 20 for allowing insertion is reduced compared to the case in which the thermocouple guide 70 is not fixed.
Furthermore, in semiconductor processes, a conventional heater has an issue with the thermocouple displacement since the thermocouple guide 70 is not fixed, but in the present disclosure, the thermocouple guide 70 is fixed to fix the thermocouple in position without movement, thereby enhancing operational durability.

In the present disclosure, the thermocouple guide 70 may have an end portion inserted and fixed to a groove of the plate 20 connected to the C-th passage part 27c and a lower side fixed to the mount 90. The thermocouple guide 70 configured of a ceramic material as described above may be configured to have a linear pipe or tube shape and have an end portion thereof inserted and fixed to a groove corresponding to the plate 20 as shown in FIG. 13, but as described below, according to various embodiments, the thermocouple guide 70 may be inserted and fixed to the plate 20 or a groove of the lower plate p1 through various methods.

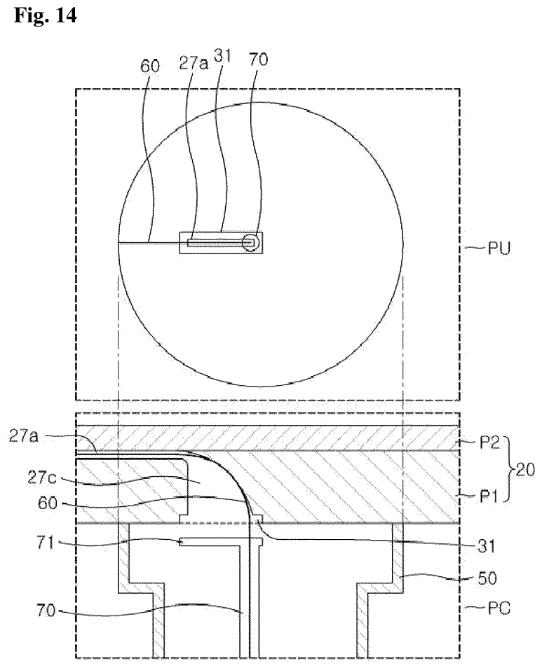

FIG. 14 is an enlarged view of another embodiment with respect to a coupling portion of a plate 20 and a shaft 50 in the sectional view taken along B-B in FIG. 1. Here, reference will be made to the sectional view PC and the planar view PU.

Referring to FIG. 14, a flat part 71 of an end portion of the thermocouple guide 70 may be inserted into and fixed to a groove 31 of the plate 20 connected to the C-th passage part 27c. The flat part 71 is inserted and fixed to the groove 31 of the plate 20 so that the thermocouple guide 70 is fixed, and the flat part 71 having a predetermined shape, such as a rectangle plate, corresponding to the shape of the groove 31 may increase an insertion area to improve the fixation force. Here, the rectangle plate-shaped flat part 71 is configured to have, at the end portion of the thermocouple guide 70, a portion extending to one side greater than a portion extending greater than the diameter of a body of the thermocouple guide 70 to the other side. The flat part 71 may be an integrated type manufactured into the corresponding shape by processing the end portion of the thermocouple guide 70 material or may be manufactured separately and coupled to the end portion of the thermocouple 70 by welding or ceramic bonding.

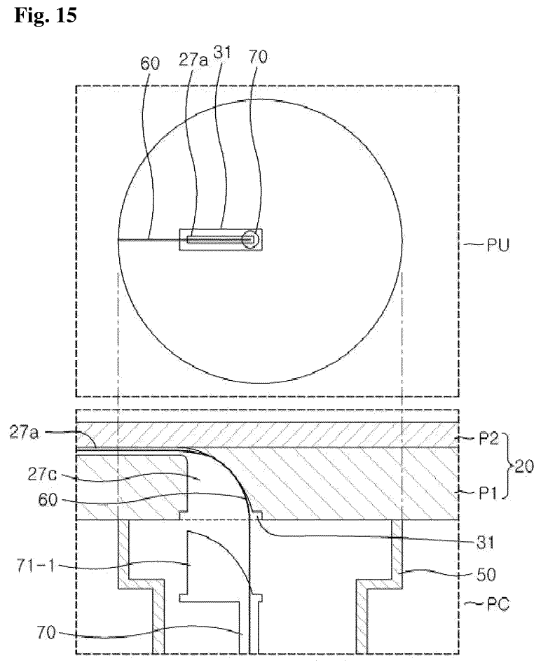

FIG. 15 is an enlarged view of still another embodiment with respect to a coupling portion of a plate 20 and a shaft 50 in the sectional view taken along B-B in FIG. 1. Here, reference will be made to the sectional view PC and the planar view PU.

Referring to FIG. 15, a filling-type protrusion part 71-1 of an end portion of the thermocouple guide 70 may be inserted into and fixed to a groove 31 of the plate 20 and the C-th passage part 27c. The filling-type protrusion part 71-1 having a shape of filling the insertion groove 31 of the plate 20 and the C-th passage part 27c may be configured to increase an insertion area, to be inserted into the C-th passage part 27c so as to improve the fixation force, and to increase the success rate of insertion. The filling-type protrusion part 71-1 may be an integrated type manufactured into the corresponding shape by processing the end portion of the thermocouple guide 70 material or may be manufactured separately and coupled to the end portion of the thermocouple 70 by welding or ceramic bonding.

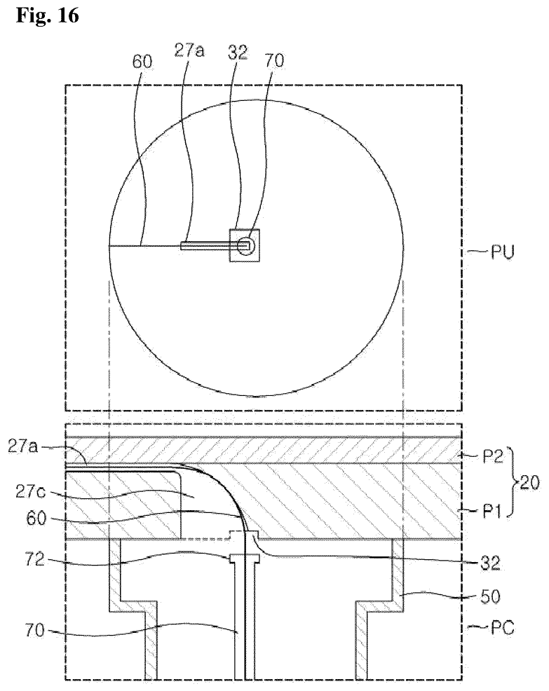

FIG. 16 is an enlarged view of still another embodiment with respect to a coupling portion of a plate 20 and a shaft 50 in the sectional view taken along B-B in FIG. 1. Here, reference will be made to the sectional view PC and the planar view PU.

Referring to FIG. 16, a flat part 72 of an end portion of the thermocouple guide 70 may be inserted into and fixed to a groove 32 of the plate 20 connected to the C-th passage part 27c. The flat part 72 is inserted and fixed to the groove 32 of the plate 20 so that the thermocouple guide 70 is fixed, and the flat part 72 having a predetermined shape, such as a rectangle plate, corresponding to the shape of the groove 32 may increase an insertion area to improve the fixation force. Here, the rectangle plate-shape flat part 72 is configured to have a square plate shape. The flat part 72 may be an integrated type manufactured into the corresponding shape by processing the end portion of the thermocouple guide 70 material or may be manufactured separately and coupled to the end portion of the thermocouple 70 by welding or ceramic bonding.

In addition to the embodiments in FIGS. 14 and 16, the flat part may be implemented at the end portion of the thermocouple guide 70, to have various shapes, such as a disc shape, various square shapes, an oval shape, a star shape. The flat part 71 or 72 of thermocouple guide 70 may increase an insertion area of the plate 20 to improve the fixation force.

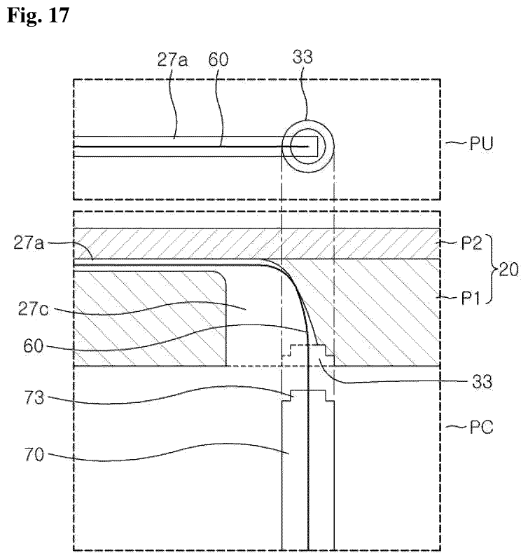

FIG. 17 is an enlarged view of still another embodiment with respect to a coupling portion of a plate and a shaft in the sectional view taken along B-B in FIG. 1. Here, reference will be made to the sectional view PC and the planar view PU.

Referring to FIG. 17, a protrusion part 73 of an end portion of the thermocouple guide 70 may be inserted into and fixed to a groove 33 of the plate 20 connected to the C-th passage part 27c. In this case, sectional shapes of the protrusion part 73 and the groove 33 of the plate 20 may be implemented to have various shapes such as a circular shape, various rectangular shapes, an oval shape, and a star shape. The protrusion part 73 of thermocouple guide 70 may improve the fixation force to reduce shaking.

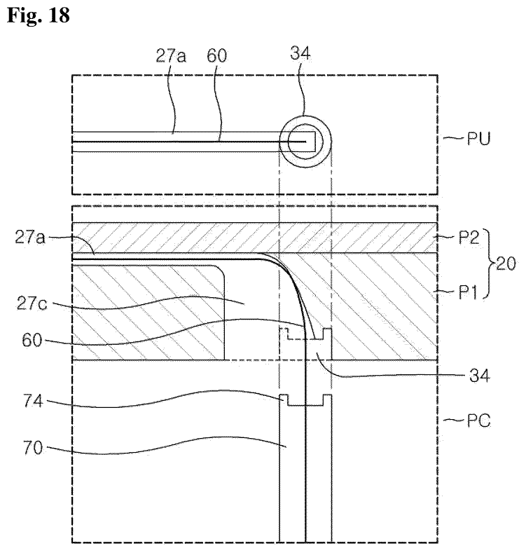

FIG. 18 is an enlarged view of still another embodiment with respect to a coupling portion of a plate and a shaft in the sectional view taken along B-B in FIG. 1. Here, reference will be made to the sectional view PC and the planar view PU.

Referring to FIG. 18, a groove part 74 of an end portion of the thermocouple guide 70 may be inserted into and fixed to a groove (part) 34 of the plate 20 connected to the C-th passage part 27c. In this case, sectional shapes of the groove part 74 and the groove 34 of the plate 20 may be implemented to have various shapes such as a circular shape, various rectangular shapes, an oval shape, and a star shape. The groove part 74 of thermocouple guide 70 may improve the fixation force to reduce shaking, as well.

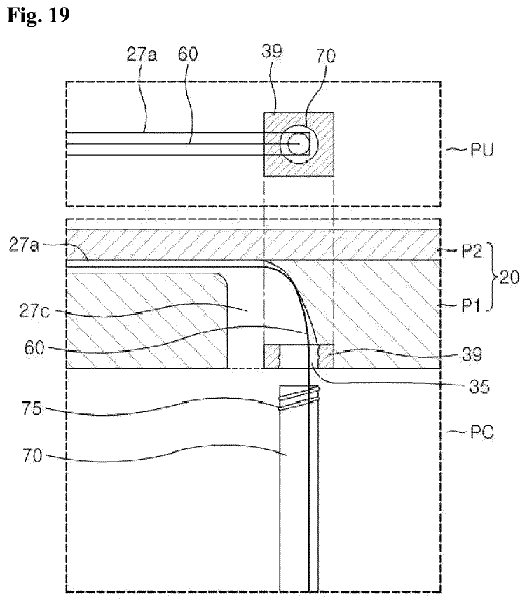

FIG. 19 is an enlarged view of still another embodiment with respect to a coupling portion of a plate and a shaft in the sectional view taken along B-B in FIG. 1. Here, reference will be made to the sectional view PC and the planar view PU.

Referring to FIG. 19, a screw part 75 (e.g., a male screw) of an end portion of the thermocouple guide 70 may be fastened (screw fastening) and fixed to a screw part 39 (e.g., a female screw) of a groove 35 of the plate 20 connected to the C-th passage part 27c. The screw part 75 of thermocouple guide 70 may improve the fixation force to reduce shaking, as well.

As such, in the present disclosure, specific matters such as specific components, etc., and limited embodiments and drawings have been described, but these are only provided to help a more general understanding of the present disclosure, and the present disclosure is not limited to the above embodiments. Those of ordinary skill in the field to which the present disclosure pertains will be able to make various modifications and variations without departing from the essential characteristics of the present invention. Therefore, the spirit of the disclosure should not be limited to the above-described embodiments, and it should be construed that the following claims as well as all technical ideas modified equally or equivalently to the claims are intended to fall within the scope and spirit of the disclosure. Furthermore, each of the above embodiments may be operated in combination with each other as needed.

What is claimed is:

1. A ceramic heater comprising:
a plate having a heat-generation body and a first passage;
a shaft having a hollow; and
a thermocouple inserted into the first passage,
wherein the first passage comprises:
an A-th passage part parallel with a first surface of the plate; and
a B-th passage part inclined with respect to the first surface.

2. The ceramic heater of claim 1, wherein the plate comprises a first plate part and a second plate part,
the A-th passage part is located in the first plate part, and
the B-th passage part is located in the second plate part.

3. The ceramic heater of claim 1, wherein the B-th passage part is inclined in a direction to the heat-generation body.

4. The ceramic heater of claim 1, wherein the B-th passage part is located at an end portion of the first passage in a direction to circumference.

5. The ceramic heater of claim 1, wherein an exit area of the A-th passage part is smaller than an entrance area of the B-th passage part.

6. The ceramic heater of claim 1, wherein a temperature measurement part of the thermocouple is located in the B-th passage part.

7. A ceramic heater comprising:
a plate having a heat-generation body and a first passage;
a shaft having a hollow; and
a thermocouple inserted into the first passage,
wherein the first passage comprises:
an A-th passage part parallel with an upper surface of the plate; and
a C-th passage part disposed between the A-th passage part and an upper end portion of the shaft and gradually narrowing from the upper end portion of the shaft to the A-th passage.

8. The ceramic heater of claim 7, further comprising a thermocouple guide disposed inside the hollow of the shaft and having an upper end portion meeting the C-th passage part,
wherein the thermocouple is located in the A-th passage part, the C-th passage part, and the thermocouple guide.

9. The ceramic heater of claim 8, wherein an end portion of the thermocouple guide is inserted into and fixed to a groove of the plate connected to the C-th passage part.

10. The ceramic heater of claim 8, wherein a flat part of an end portion of the thermocouple guide is inserted into and fixed to a groove of the plate connected to the C-th passage part.

11. The ceramic heater of claim 8, wherein a filling-type protrusion part of an end portion of the thermocouple guide is inserted into and fixed to a groove of the plate and the C-th passage part.

12. The ceramic heater of claim 8, wherein a protrusion part of an end portion of the thermocouple guide is inserted into and fixed to a groove of the plate connected to the C-th passage part.

13. The ceramic heater of claim 8, wherein a groove part of an end portion of the thermocouple guide is inserted into and fixed to a groove of the plate connected to the C-th passage part.

14. The ceramic heater of claim 8, wherein a screw part of an end portion of the thermocouple guide is fastened and fixed to a screw part of a groove of the plate connected to the C-th passage part.
